(19) United States
(12) Patent Application Publication
(10) Pub. No.: US 2008/0003823 A1
(43) Pub. Date: Jan. 3, 2008

(54) Method of manufacturing semiconductor device

(75) Inventors: Whee Won Cho, Chungcheongbuk-do (KR); Seung Hee Hong, Seoul (KR); Suk Joong Kim, Seoul (KR); Cheol Mo Jeong, Kyeongki-do (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Kyoungki-do (KR)

(21) Appl. No.: 11/647,765

(22) Filed: Dec. 29, 2006

(30) Foreign Application Priority Data
Jun. 28, 2006 (KR) 2006-58712

(51) Int. Cl. H01L 21/44; H01L 21/465

(52) U.S. Cl. 438/674; 438/740; 438/700

(57) ABSTRACT

A method of manufacturing a semiconductor device includes the steps of forming an interlayer insulating layer and an etch-stop nitride layer over a semiconductor substrate, etching the etch-stop nitride layer and the interlayer insulating layer to form contact holes, forming contacts in the contact holes, forming an oxide layer on the entire surface including the contacts, etching the oxide layer using the etch-stop nitride layer as a target, thus forming trenches through which the contacts and the etch-stop nitride layer adjacent to the contacts are exposed, and forming bit lines in the trenches.

### BACKGROUND OF THE INVENTION

1. Field of the Invention

The invention relates to semiconductor devices and, more particularly, to a method of manufacturing a semiconductor device, which can decrease RC delay by reducing capacitance between bit lines.

2. Related Technology

FIGS. 1A to 1C are cross-sectional views illustrating a conventional method of manufacturing a semiconductor device.

Referring to FIG. 1A, an interlayer insulating layer 11 is formed over a semiconductor substrate 10 in which structures (not shown) are formed. Contact holes through which specific portions of the semiconductor substrate 10 are exposed are formed in the interlayer insulating layer 11. The contact hole is filled with a conductive layer, thus forming lower contacts 12.

An etch-stop nitride layer 13 and an oxide layer 14 are sequentially formed on the entire surface including the lower contacts 12.

Referring to FIG. 1B, the oxide layer 14 is etched using the etch-stop nitride layer 13 as a stopper, thus forming trenches 15. The etch-stop nitride layer 13 below the trenches 15 is removed by an over-etch process, thereby exposing the lower contacts 12 and a specific portion of the interlayer insulating layer 11 adjacent to the lower contacts 12. At this time, the interlayer insulating layer 1I1 below the etch-stop nitride layer 13 is etched to a desired specific thickness.

Referring to FIG. 1C, a barrier metal layer (not shown) is formed on the entire surface including the trenches 15. A conductive layer is formed to fill the trenches 15. A polishing process is performed so that the oxide layer 14 is exposed, thus forming bit lines 16.

In the prior art, a total thickness of the etch-stop nitride layer 13 is located between the bit lines 16. The nitride layer has a dielectric constant twice higher than that of the oxide layer, resulting an increased bit line capacitance. Accordingly, RC delay is increased.

### SUMMARY OF THE INVENTION

The invention is directed to a method of manufacturing a semiconductor device, which can decrease RC delay by reducing capacitance between bit lines.

In one embodiment, a method of manufacturing a semiconductor device includes the steps of forming an interlayer insulating layer and an etch-stop nitride layer over a semiconductor substrate, and etching the etch-stop nitride layer and the interlayer insulating layer to form contact holes, forming contacts in the contact holes, forming an oxide layer on the entire surface including the contacts, etching the oxide layer using the etch-stop nitride layer as a target, thus forming trenches through which the contacts and the etch-stop nitride layer adjacent to the contacts are exposed, and forming bit lines in the trenches.

### BRIEF DESCRIPTION OF THE DRAWINGS

FIGS. 1A to 1C are cross-sectional views illustrating a conventional method of manufacturing a semiconductor device.

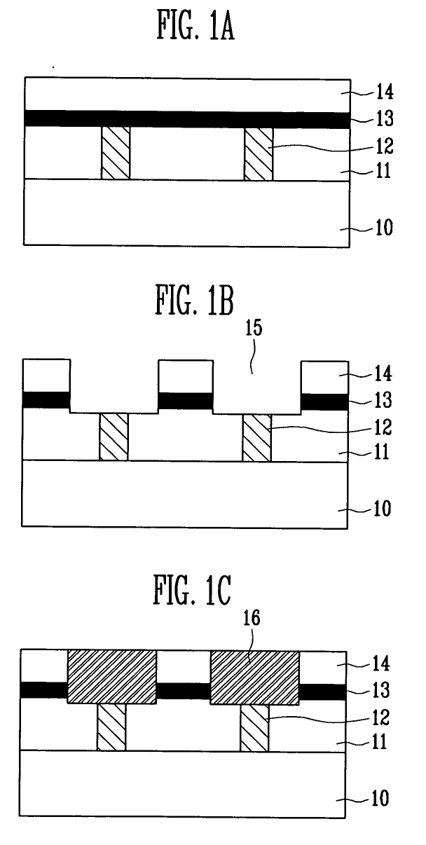

FIGS. 2A to 2C are cross-sectional views illustrating a method of manufacturing a semiconductor device according to an embodiment of the invention.

### DESCRIPTION OF SPECIFIC EMBODIMENTS

A specific embodiment according to the invention is described below with reference to the accompanying drawings.

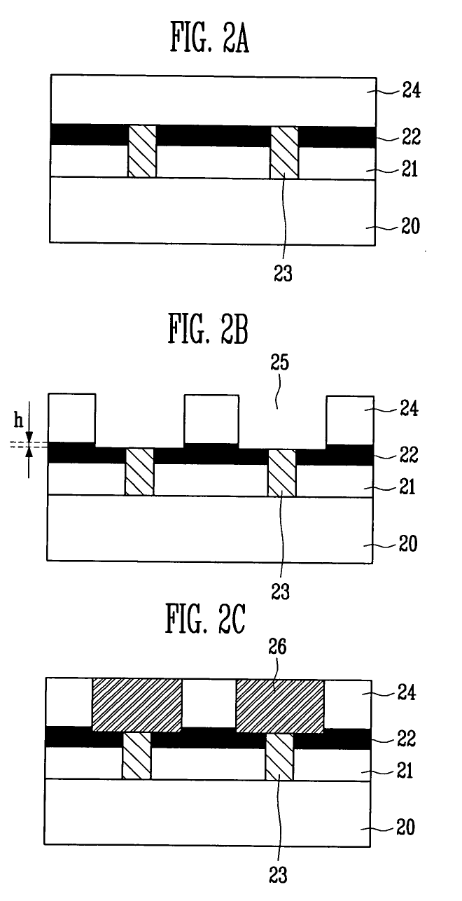

FIGS. 2A to 2C are cross-sectional views illustrating a method of manufacturing a semiconductor device according to an embodiment of the invention.

Referring to FIG. 2A, an interlayer insulating layer 21 and an etch-stop nitride layer 22 are sequentially formed over a semiconductor substrate 20 having structures formed therein.

The etch-stop layer 22 and the interlayer insulating layer 21 are etched to form contact holes through which portions of the semiconductor substrate 20 are exposed. The contact holes are filled with a conductive layer to form lower contacts 23.

An oxide layer 24 is formed on the entire surface including the lower contacts 23. The oxide layer 24 may include a general oxide layer, but preferably includes an oxide layer to which F (fluorine) having a dielectric constant of about 3.7, which is lower than the dielectric constant of about 4.2 of a general oxide layer having is added (that is, an F oxide layer).

Referring to FIG. 2B, the oxide layer 24 is etched using the etch-stop nitride layer 22 as a stopper, thereby forming trenches. 25 through which the lower contacts 23 and specific portions of the etch-stop nitride layer 22 adjacent to the lower contacts 23 are exposed. At this time, the etch-stop nitride layer 22 is also etched to a thickness of about 10 Å to 200 Å.

Since the etch stop of the trenches 25 stops at the etch-stop nitride layer 22, the trenches 25 have a constant depth.

Referring to FIG. 2C, a barrier metal layer (not shown) is formed on the entire surface including the trenches 25. A conductive layer is formed to fill the trenches 25. A polishing process is performed so that the oxide layer 24 is exposed, thereby forming bit lines 26.

The oxide layer 24 having a low dielectric constant is filled between the bit lines 26. A portion of the etch-stop nitride layer 22 having a high dielectric constant is small. Thus, in the case where bit lines having the same thickness are formed, the bit line capacitance can be decreased by about 10%.

In the prior art, the etch-stop nitride layer of about 300 Å in thickness and the oxide layer of about 1200 Å in thickness exist between the bit lines. Accordingly, an inter-bit line capacitance Cb is 300* the dielectric constant (8) of the nitride layer+1200* the dielectric constant (4.2) of the oxide layer, that is, about 7740.

In the invention, however, the nitride layer having a thickness h (refer to FIG. 2B) Å and the oxide layer having a thickness (1500-h) Å exist between the bit lines. Thus, the inter-bit line capacitance Cb becomes h* the dielectric constant (8) of the nitride layer+(1500-h)* the dielectric constant (4.2) of the oxide layer.

Accordingly, when h is 150 Å, the inter-bit line capacitance becomes 6870. Accordingly, there is an advantage in that the inter-bit line capacitance is reduced by about 7.7%. When h is 100 Å, the inter-bit line capacitance becomes 6680. Accordingly, there is an advantage in that the inter-bit line capacitance is reduced by about 10.3%.

Furthermore, if FSG (dielectric constant of 3.7) having a low dielectric constant is used the oxide layer, the bit line capacitance can be reduced more effectively.

As described above, the invention has the following advantages.

After the etch-stop nitride layer is formed, the lower contacts are formed. When etching the trenches, a portion of the etch-stop nitride layer is etched in order to reduce the thickness of the nitride layer existing between the bit lines. Accordingly, bit line capacitance can be lowered and RC delay can be decreased.

Furthermore, an oxide layer to which fluorine (F) having a low dielectric constant is added used as the oxide layer. It is therefore possible to reduce inter-bit line capacitance and also to decrease RC delay.

The distinct embodiment of the invention is illustrative and not limiting. Various alternatives and equivalents are possible. Other additions, subtractions, or modifications are intended to fall within the scope of the inventions as defined in the appended claims.

What is claimed is:

1. A method of manufacturing a semiconductor device, comprising the steps of:
forming an interlayer insulating layer and an etch-stop nitride layer over a semiconductor substrate, and etching the etch-stop nitride layer and the interlayer insulating layer to form contact holes;
forming contacts in the contact holes;
forming an oxide layer on the entire surface including the contacts;
etching the oxide layer using the etch-stop nitride layer as a target, thus forming trenches through which the contacts and the etch-stop nitride layer adjacent to the contacts are exposed; and
forming bit lines in the trenches.

2. The method of claim 1, wherein the oxide layer includes an oxide layer comprising added fluorine (F).

3. The method of claim 1, comprising etching a portion of the etch-stop nitride layer when etching the trenches.

4. The method of claim 3, comprising etching the nitride layer to a thickness of 10 Å to 200 Å.
